(19) United States
(12) Patent Application Publication
(10) Pub. No.: US 2024/0028803 A1
(43) Pub. Date: Jan. 25, 2024

(54) PARAMETERIZED HIGH LEVEL HIERARCHICAL MODELING, AND ASSOCIATED METHODS

(71) Applicant: Silicon Technologies, Inc., Midvale, UT (US)

(72) Inventors: Thomas L. Wolf, Midvale, UT (US); Alec S. Adair, Midvale, UT (US); Stuart T. Anderson, Midvale, UT (US); Kyler C. Fillerup, Orem, UT (US); Tracy L. Johancsik, Murray, UT (US); Jared Bytheway, Midvale, UT (US)

(21) Appl. No.: 18/356,983

(22) Filed: Jul. 21, 2023

Related U.S. Application Data
(60) Provisional application No. 63/369,058, filed on Jul. 21, 2022.

(51) Int. Cl. G06F 30/3308; G06F 30/333

(52) U.S. Cl. CPC G06F 30/3308; G06F 30/333

(57) ABSTRACT

A method may include obtaining a netlist representation of a circuit comprising a single-cell (S-Cell) or multi-cell (M-Cell), performing one or more test simulations using the netlist representation of the circuit, receiving one or more parameters comprising performance metrics of the circuit responsive to the one or more test simulations, and generating a parameterized model of the circuit responsive to the one or more parameters.

### TECHNICAL FIELD

This disclosure relates generally modeling analog circuits to simulate circuits using an abstracted circuit model.

### BACKGROUND

Electric modeling of analog circuits may allow an engineer to simulate functions of the circuit to measure performance properties without having to physically build the analog circuit. In some cases, circuit designers may use programs such as SPICE to electrically model analog circuits and generate detailed netlist definitions of a circuit. Moreover, “high level” languages such as Verilog, SystemC, and VHDL may be used to generate an abstracted model of a circuit relative to a netlist definition of a circuit at the cost of accuracy of the circuit model.

### BRIEF SUMMARY

Some embodiments of the present disclosure may include a non-transitory computer-readable storage medium storing instructions thereon that, when executed by at least one processor, perform acts including obtaining a netlist representation of a circuit comprising a single-cell (S-Cell) or multi-cell (M-Cell), performing one or more test simulations using the netlist representation of the circuit, receiving one or more parameters comprising performance metrics of the circuit responsive to the one or more test simulations, and generating a parameterized model of the circuit responsive to the one or more parameters.

Additional embodiments of the present disclosure include a method that may include obtaining a netlist representation of a circuit comprising a single-cell (S-Cell) or multi-cell (M-Cell), performing one or more test simulations using the netlist representation of the circuit, receiving one or more parameters comprising performance metrics of the circuit responsive to the one or more test simulations, and generating a parameterized model of the circuit responsive to the one or more parameters.

Further embodiments of the present disclosure may include a method that may include extracting one or more parameters responsive to one or more test simulations of a netlist definition of a circuit and generating one or more circuit models responsive to the one or more extracted parameters.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 illustrates an example hierarchical circuit structure of a circuit according to one or more embodiments of the present disclosure;

FIG. 2 depicts an example flowchart of a method related to generating a parameterized model of at least part of a circuit according to one or more embodiments of the present disclosure;

FIG. 3 shows example Verilog code illustrating one possible implementation of a circuit model template for an inverter according to one or more examples; and

FIG. 4 is a block diagram of circuitry that, in some examples, may be used to implement various functions, operations, acts, processes, and/or methods disclosed herein.

### DETAILED DESCRIPTION

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure, or manner.

In the present disclosure, the term “cell” may refer to a unit that is a component part of an integrated circuit. A cell may be a container for various models (e.g., models of circuit elements e.g., resistors, capacitors, and transistors), data structures, shapes, annotations, and even references to other cells. Some cells may be relatively simple, e.g., containing one element, or being empty of data. Other cells may be relatively complex, e.g., containing the entirety of a billion-transistor processor.

In the present disclosure, the terms “high level” or “abstracted” used with regard to circuit descriptions or languages may refer to a description or language with one or more abstractions relative to a more complete or technical circuit description or description language. For example, a “high level” or “abstracted” description of a circuit may be a description with one or more abstracted components compared to a netlist definition of the circuit. As a specific example, Verilog-A can be considered to be a “high level” or “abstracted” language compared to a netlist definition of a circuit.

Electric modeling of analog circuits may allow a circuit designer to simulate performance metrics of a circuit without the need to physically build the analog circuit. In some cases, designers may use circuit design programs like SPICE to define an electric model of an analog circuit. However, SPICE and like programs generate robust and detailed netlist definitions of circuits defining a circuit down to a transistor level and are typically manually defined which may be extremely time intensive to create and simulate (e.g., taking hours or even days, depending on the complexity of the circuit). Moreover, “high level” abstraction languages such as Verilog, SystemC, and VHDL, while faster to simulate, have not been shown to be accurate enough to effectively model analog circuits based on conventional usage techniques.

For example, high level circuit model descriptions can treat circuits as ideal, (e.g., by not taking into account an actual circuit's performance) and simulations can be performed on these ideal circuit models to measure performance of a circuit. However, this approach is generally considered too inaccurate to reliably indicate a circuit's performance, particularly in analog design where circuit performance is almost always different from what the performance would be in an ideal case. As another example, a high level circuit model description may be tested (e.g., subjected to one or more test simulations) to obtain key parameters that allow the modeled circuit to more accurately reflect the characteristics of the design. In this approach, designers typically perform these tests manually and generate the modeled design manually, which may take an impractical amount of time. Moreover, this approach allows for human error and also makes it difficult to ensure that tests are performed in a consistent fashion, particularly when modeling the same types of devices across multiple different types of foundry processes. Accordingly, these options may be considered to be either too time-consuming or inaccurate for practical applications. As a result, “high level” modeled cells are used infrequently in analog design.

Accordingly, to provide a way to generate a high level or abstracted circuit model with sufficiently accurate performance characteristics, a method may be provided to generate a circuit model using a universal testbench approach to apply test simulations to a netlist definition of a circuit to populate a circuit model template. For example, a netlist may be generated defining a circuit where one or more test simulations may be performed via a universal testbench using the netlist definition of the circuit. Responsive to the one or more test simulations, one or more parameters representative of performance characteristics of at least part of the circuit may be obtained and used to populate a circuit model template to generate a parameterized circuit model. The parametrized circuit model may an abstract representation of a more detailed underlying structure which may then be used in subsequent simulations that will give sufficiently accurate information compared to that that of the netlist definition of the circuit while requiring a small fraction of the time to simulate.

For example, the parameterized circuit model may be a model for a digital to analog converter (DAC) where, if one were to simulate the netlist representation of the DAC, the simulation would simulate each part of the netlist representation of the DAC down to the transistor level requiring complicated mathematical calculations for potentially thousands or more components. However, by using an abstracted model, the performance characteristics of the DAC may be captured with sufficient accuracy that a parameterized DAC model may be used to simulate operation of the DAC in a fraction of the time comparted to a detailed netlist representation of the DAC. Moreover, a parameterized model may be created for any structure within a hierarchical definition of a circuit. Accordingly, using a template and a universal test system to automatically generate a modeled circuit may significantly decrease circuit simulation time while also providing accurate behavior of the modeled circuit by extracting performance characteristic parameters from a detailed simulation of a netlist representation of the circuit and also providing a model that is topology, foundry and/or circuit-representation agnostic, thus allowing the model to be used in a variety of contexts without needing to re-simulate the circuit in a netlist form for each different iteration of testing.

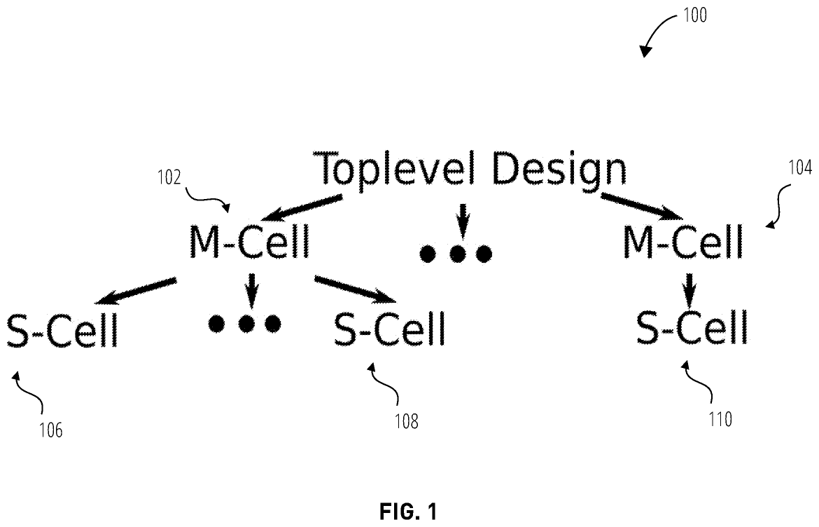

FIG. 1 illustrates an example hierarchical circuit structure 100 of a circuit according to one or more embodiments of the present disclosure. For example, the hierarchical circuit structure 100 illustrates a top-level design of a circuit that includes multiple multi-cell (M-Cell) circuits 102 and 104 which, in turn, include one or more single-cell (S-Cell) circuits 106, 108, and 110. In one or more embodiments, a parameterized model may be created for one or more levels or nodes of a hierarchical circuit structure (e.g., hierarchical circuit structure 100). For example, a parameterized model may be created for each S-Cell 106, 108, and 110 of the hierarchical circuit structure 100 as well as each M-Cell 102, and 104 of the hierarchical circuit structure 100, which may all be generated and used separately. This may allow for high level testing early in a design process by easily and quickly using modeled circuit designs to estimate performance. Any level of a device may be modeled, down to individual transistors and other primitive cell types.

When obtaining parameters that a modeled circuit may include in order to be accurate to the design, the lower hierarchy circuit elements may be irrelevant. For example, if certain parameters (e.g., identified relevant parameters) are taken into account, not all circuit performance characteristics need to be considered. For example, a current-mirror operational amplifier (OPAMP) and a folded-cascode OPAMP— if they have the same pin configurations then the number of transistors/net connections inside may not meaningfully differentiate the two OPAMPs for testing purposes and both may have various performance-related parameters measured and a parameterized model generated using the same universal testbench. As another example, a low-voltage-threshold single transistor may be measured the same as a typical-voltage-threshold or super-low-voltage threshold device.

Accordingly, any structure in the hierarchical circuit structure 100 may be modeled as discussed herein such that the modeled circuit structure may be easily swapped in or out of a design depending on the needs of a circuit designer to allow for faster simulations to be performed on the modeled circuit structure to gauge performance of the modeled circuit structure without having to simulate a detailed netlist definition of the circuit structure. As yet another example, an M-Cell 102 may represent a DAC and S-Cells 106 and 108 below the M-Cell in a hierarchical circuit structure (e.g., hierarchical circuit structure 100) may represent various OPAMPS included in the DAC. A parameterized model may be generated for the DAC representing an abstracted representation of the DAC having various performance metrics without needing to measure the performance metrics of each OPAMPS in the hierarchy below the DAC. This parameterized DAC model may then be used interchangeably by a circuit designer to quickly build and simulate a circuit design including the parameterized DAC model. Moreover, A parameterized model of an OPAMPS may be generated for a circuit designer to build and simulate circuit designs including OPAMPS if the circuit designer wishes to build a circuit at a more detailed level (e.g., lower hierarchical level) than that of the DAC.

Furthermore, a topology (e.g., a netlist definition) of an M-Cell may have the same tests (e.g., via the universal testbench) performed on it to obtain sufficiently accurate parameters for generating an abstracted circuit model of the M-Cell. For example, such tests may include transient, DC, noise, AC, and other types of tests. Once the tests are completed, parameters may be extracted responsive to the tests and used to generate an abstracted circuit model (e.g., a model defined using the Verilog-A description language). The circuit model may accurately reflect any original circuit representation—this may be particularly useful for circuit representations that take much longer to simulate. The modeled circuit may run much faster than the original, completing simulations in multiple orders of magnitude less time than would have otherwise been required. Circuit representations that otherwise do not allow for a large amount of testing, or testing at higher level in a design, retain a high level of accuracy with the modeled circuits.

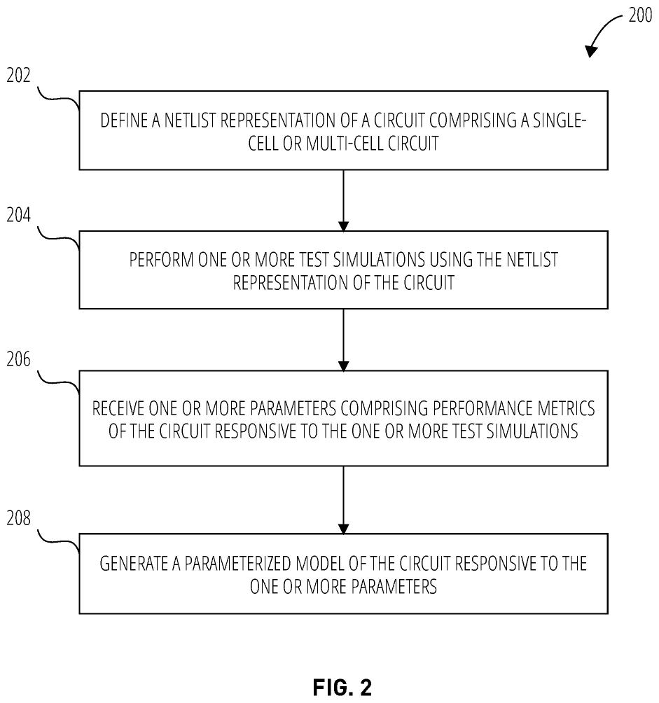

FIG. 2 depicts an example flowchart of a method 200 related to generating a parameterized model of at least part of a circuit according to one or more embodiments of the present disclosure. More specifically, FIG. 2 depicts a methodology for obtaining performance parameters from one or more simulations of a netlist to populate parameters defined in a model template. The method may include defining a netlist representation of a circuit comprising a S-Cell or M-Cell circuit, as shown in block 202. In one or more embodiments, a netlist for a circuit may be generated automatically responsive to a script for a predetermined circuit type. For example, a user may be able to access one or more scripts where each of the one or more scripts may be configured to generate a netlist for a particular circuit, process, or foundry type. As a specific example, a user may select a script for generating a netlist for an OPAMP and, responsive to the selection, the selected script may run and automatically generate a netlist defining an OPAMP. In some embodiments, the scripts may be used to generate a netlist regardless of a circuit type for every cell in a given process.

Upon selection of a script, the script may analyze a circuit design and characterize the circuit. For example, some embodiments may generate a text file of all elements in a circuit using a hierarchy structure, defining all circuits and test devices (e.g., a netlist) of a circuit design. The netlist may be based on various netlist templates e.g., process-specific templates and/or design-specific templates. Process-specific-netlist aspects may include parameters specific to a process (e.g., a variable for power supply voltage). Design-specific-netlist aspects may include parameters specific to a cell type (e.g., a testbench to test a latch will have different switches and stimuli than is necessary to test an OPAMP). The design may have been ported from a different transistor technology size or designed in the current process.

Upon defining a netlist representation of the circuit, one or more test simulations may be performed using the netlist representation of the circuit, as shown in block 204 of method 200. For example, in the case of a netlist defining a clock generator, one or more test simulations may be run on the clock generator using the netlist definition of the clock generator. In one or more embodiments, a universal S-Cell or M-Cell testbench template may run the necessary simulations. For example, a universal S-Cell or M-Cell testbench template may automatically apply one or more predetermined test simulations for a known circuit type. The universal testbench may be topology-independent, foundry independent and/or circuit-representation independent.

In one or more embodiments a predetermined circuit model template may be obtained where the circuit model template represents an abstracted (i.e., “high level”) definition (e.g., a template generated using Verilog-A) of a circuit relative to the netlist definition of the circuit. The circuit model template may define one or more parameter variables that define performance characteristics of the circuit defined by the template. In some embodiments the predetermined circuit model template may be selected from a plurality of circuit model templates where the selected circuit model template corresponds to the circuit defined by the netlist. Moreover, the tests run on the netlist representation of the circuit may be selected based on the parameters of a circuit model template. For example, a test may be selected known to produce information relating to Parameter X responsive to Parameter X being present in the circuit model template corresponding to the circuit defined by the netlist.

Returning to the example where the netlist defines a clock generator, as a result of the one or more test simulations, one or more parameters, including output values including one or more of rise time, fall time, propagation delay, current consumption, output impedance, may be generated where each of the one or more parameters may indicate performance metrics of the clock generator responsive to the test simulations. These parameters may be received or otherwise obtained responsive to the one or more test simulations being performed on a netlist definition of a circuit, as shown in block 206 of method 200. For example, in one or more embodiments, the parameters may be selected based on the model template being used, as discussed above. For example, one or more parameters may be obtained responsive to one or more test simulations run on a netlist definition of an OPAMP based on parameters defined in a model template for an OPAMP.

In one or more embodiments, the one or more parameters may be formatted into one or more mathematical expressions (e.g., one or more mathematical expressions generated responsive to one or more curve fitting techniques) or as a lookup table. For example, a single transistor may be modeled by obtaining parameters responsive to test simulations of a netlist definition of the transistor to describe the transistor using the Square Law, or by replicating exact values through use of a look up table system. Choosing which type of modeling is appropriate is up to the designer, what applications the abstracted model needs to be accurate in and is often technology dependent.

Once the one or more parameters have been obtained, the one or more parameters may then be used to generate a parameterized model of the circuit. For example, once obtained, the one or more parameters may then be inserted into the circuit model template to the corresponding parameter variables defined within the circuit model template. This template may then be used to accurately approximate the original design's performance across a range of test types and conditions. The updated circuit model template may be referred to herein as a “parameterized circuit model.” The parameterized circuit model may be a new cell representation defining an abstracted representation of a circuit defined by directly measured values responsive to the one or more test simulations. As a specific example, in the example of the clock generator, a parameterized circuit model of the clock generator may be generated responsive to updating a clock generator model template using values extracted or otherwise obtained from performing one or more test simulations on a netlist representation of the clock generator.

In some embodiments, when foundry-specific parameters are inserted into the template, an S-Cell or M-Cell being modeled may be from any foundry. For example, the parametrized model of the S-Cell or M-Cell may be topology, foundry, and/or circuit representation independent.

In some embodiments, a modeled circuit may be developed from ideal circuit characteristics, one with extracted layout characteristics, a design developed for Radiation Hardening (RAD-HARD) performance, or other circuit representations.

After the parameterized circuit model has been generated, the parameterized circuit model may be simulated. As a result of populating a circuit model template using parameters obtained by running test simulations on a netlist definition of a circuit, the parameterized circuit model may, when subject to test simulations, provide results that are informed by the actual performance of the representation of the original circuit (i.e., the performance of the netlist of the simulated circuit, e.g., the clock generator or single transistor).

Moreover, as a result, the parameterized circuit model may be simulated and/or tested more quickly than the netlist while maintaining substantial accuracy for reliable test results for circuit design. For example, it may be possible to perform tests on the updated high level model template of the clock generator more quickly than it may be possible to perform the same tests on the netlist of the clock generator. Nevertheless, the results of the tests on the parameterized circuit model may exhibit substantially the same accuracy as the results of performing the tests on the netlist.

Accordingly, the parameterized circuit model may be independent of test conditions, which may allow for greater flexibility when designing a circuit. For example, it may be beneficial for a designer to see a circuit's performance across a range of expected performances, or corners—corners may include variations in temperature, power supply, and transistor and other primitive cell performances. Once an S-Cell or M-Cell is modeled across a set of corners, the designer may be enabled to select whichever corner is desired for simulation. A designer may even be enabled to test different modeled devices as different corners, an option that may typically be unavailable.

In addition to corners, which vary across an entire circuit in the same way, designers may be enabled to use test types such as Monte Carlo simulations to replicate a condition where not all devices have the same variation. Once the test type is modeled, the designer may be enabled to run any sort of test and have the modeled circuit accurately reflect the original's performance.

Additionally, because the parameterized circuit model is independent of the netlist definition of the circuit once it is generated, the parameterized circuit model can also be used in a different foundry or process. Performance between devices between foundries can be compared, or a hierarchical circuit structure from another process can have individual cells in the hierarchy replaced. In this way a parameterized circuit model from another process can serve as a starting point to view design needs for a unique project.

Moreover, Designers may be enabled to select which level of the hierarchy to use modeled cells versus the SPICE based on needs for speed, accuracy, and correctly modeling the electrical characteristics of the cell.

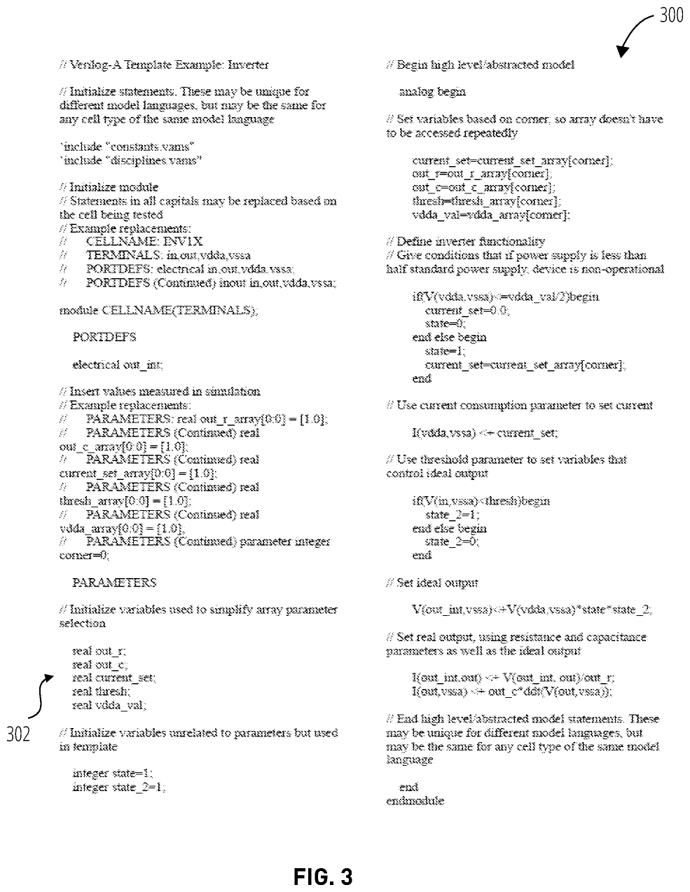

FIG. 3 shows example Verilog code illustrating one possible implementation of a circuit model template 300 for an inverter according to one or more examples. For example, one or more parameters (i.e., parameter values) that are obtained via test simulations of a netlist definition of a circuit may be used to initialize variables 302. Once the variables in the template have been initialized, the template may be referred to as a parameterized circuit model, which may be used in subsequent simulations to measure performance of the circuit. Though depicted as an example template for an inverter, any circuit type may be used and the template changed to fit the specific design of a selected circuit (e.g., using different parameters that may be unique to a certain circuit configuration).

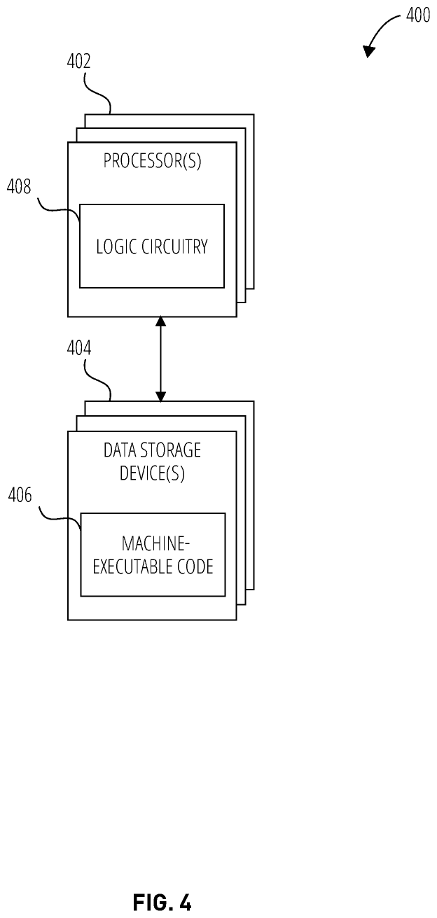

It will be appreciated by those of ordinary skill in the art that functional elements of examples disclosed herein (e.g., functions, operations, acts, processes, and/or methods) may be implemented in any suitable hardware, software, firmware, or combinations thereof. FIG. 4 illustrates non-limiting examples of implementations of functional elements disclosed herein. In some examples, some or all portions of the functional elements disclosed herein may be performed by hardware specially configured for carrying out the functional elements.

FIG. 4 is a block diagram of logic circuitry 408 that, in some examples, may be used to implement various functions, operations, acts, processes, and/or methods disclosed herein. The logic circuitry 408 includes one or more processors 402 (sometimes referred to herein as “processors 402”) operably coupled to one or more data storage devices 404 (sometimes referred to herein as “storage 404”). The storage 404 includes machine-executable code 406 stored thereon and the processors 402 include logic circuitry 408. The machine-executable code 406 includes information describing functional elements that may be implemented by (e.g., performed by) the logic circuitry 408. The logic circuitry 408 is adapted to implement (e.g., perform) the functional elements described by the machine-executable code 406. The circuitry 400, when executing the functional elements described by the 406, should be considered as special purpose hardware configured for carrying out functional elements disclosed herein. In some examples the processors 402 may perform the functional elements described by the machine-executable code 406 sequentially, concurrently (e.g., on one or more different hardware platforms), or in one or more parallel process streams.

When implemented by logic circuitry 408 of the processors 402, the machine-executable code 406 is to adapt the processors 402 to perform operations of examples disclosed herein. For example, the machine-executable code 406 may adapt the processors 402 to perform at least a portion or a totality of the sequence flow diagram 200 of FIG. 2.

The processors 402 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine-executable code 406 (e.g., software code, firmware code, hardware descriptions) related to examples of the present disclosure. It is noted that a general-purpose processor (may also be referred to herein as a host processor or simply a host) may be a microprocessor, but in the alternative, the processors 402 may include any conventional processor, controller, microcontroller, or state machine. The processors 402 may also be implemented as a combination of computing devices, such as a combination of a DSP and a microprocessor, a plurality of microprocessors, one or more microprocessors in conjunction with a DSP core, or any other such configuration.

In some examples the storage 404 includes volatile data storage (e.g., random-access memory (RAM)), non-volatile data storage (e.g., Flash memory, a hard disc drive, a solid state drive, erasable programmable read-only memory (EPROM), etc.). In some examples the processors 402 and the storage 404 may be implemented into a single device (e.g., a semiconductor device product, a system on chip (SOC), etc.). In some examples the processors 402 and the storage 404 may be implemented into separate devices.

In some examples the machine-executable code 406 may include computer-readable instructions (e.g., software code, firmware code). By way of non-limiting example, the computer-readable instructions may be stored by the storage 404, accessed directly by the processors 402, and executed by the processors 402 using at least the logic circuitry 408. Also by way of non-limiting example, the computer-readable instructions may be stored on the storage 404, transferred to a memory device (not shown) for execution, and executed by the processors 402 using at least the logic circuitry 408. Accordingly, in some examples the logic circuitry 408 includes electrically configurable logic circuitry 408.

In some examples the machine-executable code 406 may describe hardware (e.g., circuitry) to be implemented in the logic circuitry 408 to perform the functional elements. This hardware may be described at any of a variety of levels of abstraction, from low-level transistor layouts to high level description languages. At a high level of abstraction, a hardware description language (HDL) such as an IEEE Standard hardware description language (HDL) may be used. By way of non-limiting examples, VERILOG™, SYSTEMVERILOG™ or very large-scale integration (VLSI) hardware description language (VHDL™) may be used.

HDL descriptions may be converted into descriptions at any of numerous other levels of abstraction as desired. As a non-limiting example, a high level description may be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuitry 408 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine-executable code 406 may include an HDL, an RTL, a GL description, a mask level description, other hardware description, or any combination thereof.

In examples where the machine-executable code 406 includes a hardware description (at any level of abstraction), a system (not shown, but including the storage 404) may implement the hardware description described by the machine-executable code 406. By way of non-limiting example, the processors 402 may include a programmable logic device (e.g., an FPGA or a PLC) and the logic circuitry 408 may be electrically controlled to implement circuitry corresponding to the hardware description into the logic circuitry 408. Also, by way of non-limiting example, the logic circuitry 408 may include hard-wired logic manufactured by a manufacturing system (not shown, but including the storage 404) according to the hardware description of the machine-executable code 406.

Regardless of whether the machine-executable code 406 includes computer-readable instructions or a hardware description, the logic circuitry 408 is adapted to perform the functional elements described by the machine-executable code 406 when implementing the functional elements of the machine-executable code 406. It is noted that although a hardware description may not directly describe functional elements, a hardware description indirectly describes functional elements that the hardware elements described by the hardware description are capable of performing.

In accordance with common practice, the various features illustrated in the drawings may not be drawn to scale. The illustrations presented in the disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. As used herein, “and/or” includes any and all combinations of one or more of the associated listed items.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms “first,” “second,” “third,” etc., connote a specific number of elements, these terms should not be understood to connote a specific number of elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternative useful combinations of the elements described, will become apparent to those skilled in the art from the description. Such modifications and embodiments also fall within the scope of the appended claims and equivalents.

What is claimed is:

1. A non-transitory computer-readable storage medium storing instructions thereon that, when executed by at least one processor, cause the at least one processor to perform acts comprising:
obtaining a netlist representation of a circuit comprising a single-cell (S-Cell) or a multi-cell (M-Cell);
performing one or more test simulations using the netlist representation of the circuit;
receiving one or more parameters comprising performance metrics of the circuit responsive to the one or more test simulations; and
generating a parameterized model of the circuit responsive to the one or more parameters.

2. The system of claim 1, wherein the instructions stored on the non-transitory computer-readable storage medium, when executed by the at least one processor, cause the system to format the one or more parameters into one or more mathematical expressions representative of the one or more parameters.

3. The system of claim 2, wherein the one or more mathematical expressions are generated using one or more curve fitting techniques.

4. The system of claim 1, wherein the instructions stored on the non-transitory computer-readable storage medium, when executed by the at least one processor, cause the system to format the one or more parameters as a look-up table comprising the one or more parameters.

5. The system of claim 1, wherein the instructions stored on the non-transitory computer-readable storage medium, when executed by the at least one processor, cause the system to:
obtain an abstracted model template based on a S-Cell or M-Cell circuit; and
update the abstracted model template using the one or more parameters observed during the performed one or more test simulations to generate the parameterized model, wherein the parameterized model approximates performance of the circuit that tests were performed on across a range of tests.

6. The system of claim 2, wherein the parameterized model is topology independent, foundry independent and/or circuit-representation independent.

7. The system of claim 1, wherein the instructions stored on the non-transitory computer-readable storage medium, when executed by the at least one processor, cause the system to extract the one or more parameters responsive to the one or more test simulations based, at least in part, on an abstracted model template based on a S-Cell or M-Cell circuit.

8. A method comprising:
generating a description of a simulated circuit, the description comprising a netlist, the simulated circuit comprising a single-cell (S-Cell) or a multi-cell (M-Cell) circuit;
performing test simulations of the description of the simulated circuit using the netlist;
automatically extracting one or more performance parameters of the simulated circuit responsive to the test simulations; and
generating a simulated circuit model based on the one or more performance parameters.

9. The method of claim 8, further comprising:
obtaining a simulated circuit model template; and
updating the simulated circuit model template based, at least in part, on the one or more performance parameters to generate the simulated circuit model, the simulated circuit model configured to approximate performance of the simulated circuit.

10. The method of claim 9, wherein the simulated circuit model template is topology independent, foundry independent and/or circuit-representation independent.

11. The method of claim 8, wherein the test simulations comprise one or more of DC, AC, noise, and transient simulations.

12. The method of claim 8, further comprising formatting the one or more performance parameters into one or more mathematical expressions representative of the one or more performance parameters.

13. The method of claim 12, wherein the one or more mathematical expressions are generated using one or more curve fitting techniques.

14. The method of claim 8, further comprising formatting the one or more performance parameters as a look-up table comprising the one or more performance parameters.

15. The method of claim 8, wherein the simulated circuit model is topology independent, foundry independent and/or circuit-representation independent.

16. The method of claim 8, further comprising extracting the one or more performance parameters based, at least in part, on a simulated circuit model template based on the simulated circuit.

17. A method comprising:
extracting one or more parameters responsive to one or more test simulations of a netlist definition of a circuit; and
generating one or more circuit models responsive to the one or more extracted parameters.

18. The method of claim 17, further comprising:
formatting the one or more parameters as a mathematical expression responsive to fitting a curve to the one or more parameters.

19. The method of claim 17, wherein the one or more test simulations comprise one or more of transient, DC, noise, AC tests.

20. The method of claim 17, wherein the one or more circuit models are formatted to be compatible with Verilog-A.
